(19) United States
(12) Patent Application Publication
(10) Pub. No.: US 2023/0029586 A1
(43) Pub. Date: Feb. 2, 2023

(54) Temperature Control Apparatus

(71) Applicant: AVL List GmbH, Graz (AT)

(72) Inventor: Andreas MOLINARI, Hitzendorf (AT)

(21) Appl. No.: 17/962,261

(22) Filed: Oct. 7, 2022

Related U.S. Application Data
(63) Continuation of application No. PCT/AT2021/060114, filed on Apr. 6, 2021.

(30) Foreign Application Priority Data
Apr. 9, 2020 (AT) A 50307/2020

(51) Int. Cl. H01M 10/613; G05D 15/01; H01M 50/202; H01M 10/6554; H01M 10/6556; H01M 10/48; H01M 50/291; H01M 50/264

(52) U.S. Cl. CPC H01M 10/613; G05D 15/01; H01M 50/202; H01M 10/6554; H01M 10/6556; H01M 10/486; H01M 50/291; H01M 50/264

(57) ABSTRACT

Disclosed is a temperature control apparatus for accommodating a battery cell (1), where a first plate (2) and/or a second plate (3) is/are provided with at least one duct (4), and the at least one duct (4) can be filled with a temperature control medium, where the battery cell (1) can be placed between the two plates (2, 3).

### CROSS-REFERENCE TO RELATED APPLICATIONS

This application is a continuation of International Patent Application No. PCT/AT2021/060114 filed on Apr. 6, 2021, which claims the benefit of Austrian Patent Application No. A 50307/2020 filed on Apr. 9, 2020. The entire disclosures of each of the above applications are incorporated herein by reference.

### FIELD

The present disclosure relates to a temperature control apparatus for accommodating a battery cell, where the temperature control apparatus includes a first plate and a second plate. The present disclosure further relates to a system including at least two such temperature control apparatuses.

### BACKGROUND

This section provides background information related to the present disclosure which is not necessarily prior art.

Carrier units for battery cells in which the battery cells are placed on a carrier plate are known. Subsequently, the wiring of the poles is produced with high current cables or copper rail connections. Furthermore, the sensor system must be produced for the temperatures to be measured, which takes place in a more elaborate manner by adhering to the battery cell. The voltage measurement on the battery cell is carried out by screw-in contacts, which also means increased installation space. These screw-in contacts then establish a connection between the measuring point (positive, negative pole) and the connection plug. A second carrier plate is then added to this structure, which is then connected to the first carrier plate via screw connections and pressurizes the battery cell between the two plates.

In this structure, the user must additionally ensure that the sensor system (e.g., temperature sensors) cannot penetrate the battery cell and thereby destroy it.

This type of structure represents a high mechanical effort, in particular the wiring of the high current poles is very complex due to the large-diameter cable feeds.

After the assembly of these carrier units, these are then placed into a climate chamber for performing tests (charging and discharging processes at different temperatures). Plug contacts for measuring technology are located in this chamber and the connection to the sensor system (e.g., temperature, voltage, pressure) of the carrier unit is established manually by means of these plug contacts.

Furthermore, the plug connections for the high-current lines (plus, minus pole) are also established.

These processes around the carrier unit are currently purely manual processes which are time-consuming.

A rapid release or removal of the battery cell in the event of a problem (battery cell begins to “run away” thermally—i.e., it continues to heat up or in the event of a fire) is also not possible.

Furthermore, the temperature of the chamber is regulated in the climate chamber, resulting in a relatively constant temperature in the climate chamber, but not in a constant temperature at the battery cell.

Thus, the size of the battery cell and its load state leads to the temperature at the battery cell drifting far away from the regulated temperature level of the climate chamber.

### SUMMARY

This section provides a general summary of the disclosure, and is not a comprehensive disclosure of its full scope or all of its features.

According to the principles of the present disclosure, the battery tray is modified in such a way that the high mechanical effort during installation of the battery in the battery tray is minimized and at the same time an automatic equipping of the test apparatus with the battery tray is possible, as well as a drifting away of the temperature at the battery from the desired value is further avoided.

An example of a temperature control apparatus that achieves these objectives is described herein. The temperature control apparatus includes a first plate and a second plate. The first plate and/or the second plate is/are provided with at least one duct, and this at least one duct can be filled with a temperature control medium (e.g., coolant). The battery cell can be placed between the two plates. This has the advantage that the temperature of the battery cell can be regulated directly and a climate chamber is no longer required.

Preferably, the battery cell facing side of the first plate and/or battery cell facing side of the second plate has/have at least one temperature sensor not protruding from the first plate and/or second plate. In this way, mechanical damage to the battery cell by the sensors is avoided and the sensors do not have to be painstakingly fastened to the battery cell by manual work.

Also preferably, the temperature control apparatus includes at least one third plate having at least one temperature sensor that does not protrude from the third plate. In this way, too, mechanical damage to the battery cell by the sensors is avoided and the sensors do not have to be painstakingly fastened to the battery cell by manual work.

Further preferably, the battery cell is enclosed by one or more spacer plates, and the thickness of all spacer plates corresponds at least substantially to the thickness of the battery cell. The battery cell is thus well placed.

Further preferably, the temperature control apparatus includes a fourth plate for making electrical contact with the battery cell. Thus, the current-conducting cables need not be connected manually to the battery cell.

Further preferably, the at least one spacer plate can enclose the battery cell in such a way that at least two connectors of the battery cell can rest flat on the fourth plate for electrical contacting. This avoids mechanical stress on the connectors of the battery cell.

Further preferably, the ducts of the first plate and/or of the second plate are connected to at least one coupling which enables an inflow and/or outflow of the temperature control medium. A simple connection of the temperature control apparatus to a cooling system is thus possible.

Further preferably, the at least one coupling can be automatically actuated by a coupling actuator. An automatable connection of the temperature control apparatus to a cooling system is thus possible.

Further preferably, the first plate and/or the second plate and/or the third plate has/have at least one temperature adjustment mechanism, and the at least one temperature adjustment mechanism is designed such that it can selectively control the temperature of the battery cell due to its positioning. Thus, a certain temperature that deviates from the other temperature of the battery cell can be achieved at a specific position on the battery cell.

Further preferably, the temperature control apparatus additionally includes at least one force sensor, and the force sensor is designed such that it can determine the force acting on the battery cell. Thus, during operation, it is possible to make an inference about the expansion or contraction of the battery cell by measuring the force.

Further preferably, the temperature control apparatus includes a force actuator that is designed such that, despite an expansion of the battery cell, the clamping force of the battery cell remains constant. Thus, tests can be carried out under constant conditions and are therefore comparable.

Further preferably, the force sensor and/or the force actuator is a piezocrystalline or a piezoelectric or a magnetostrictive element. Thus, the measurement and the application of the force can be effected by the same element.

Further preferably, at least two temperature control apparatuses are integrated into a system, the temperature control apparatuses are connected to a cooling system, and the cooling system includes at least one pressure accumulator. Thus, a plurality of temperature control apparatuses can be operated in parallel.

Further preferably, the cooling system further includes an overpressure valve which is designed such that temperature control medium and/or steam of the temperature control medium can escape via the overpressure valve. Thus, in the event of overheating of the temperature control medium, an excessively high pressure in the cooling system can be avoided.

Further preferably, the temperature control apparatuses are arranged in such a way that they can be separated individually from the system in case of danger. This ensures that the operation of the other temperature control apparatuses can be maintained and the endangering battery cell can be quickly brought into a safe area.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 shows an exploded perspective view of a temperature control apparatus according to the principles of the present disclosure.

FIG. 2 shows a perspective view of a plate with integrated temperature adjustment mechanisms according to the principles of the present disclosure.

FIG. 3 shows a sectional view of plates having integrated temperature adjustment mechanisms with a battery cell in an installed state according to the principles of the present disclosure.

FIG. 4 shows a sectional view of a temperature control apparatus including a force actuator and a force sensor according to the principles of the present disclosure.

Corresponding reference numerals indicate corresponding parts throughout the several views of the drawings.

### DETAILED DESCRIPTION

Example embodiments will now be described more fully with reference to the accompanying drawings.

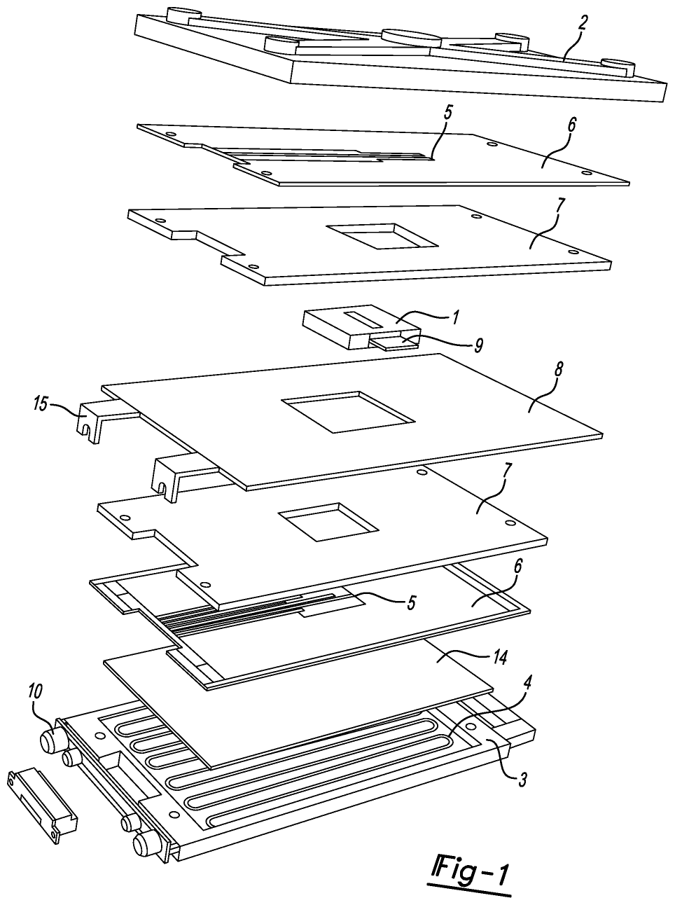

FIG. 1 shows an embodiment of a temperature control device or apparatus according to the present disclosure. A first plate (2) and a second plate (3) are each located on the very outside, then followed in this embodiment by two plates (6), each of which has a plurality of temperature sensors (5) that do not protrude from the plates (6). Then followed by spacer plates (7), which ensure that a battery cell (1), which is enclosed by the spacer plates (7), is placed in such a way that connectors (9) of the battery cell (1) rest flat on a plate (8) for electrical contacting.

In the second plate (3), a coolant channel or duct (4) is introduced through milled-out portions. The second plate (3) is provided on the front side with two bores which contact couplings (10). The couplings (10) ensure a connection to an external supply or source of the temperature control medium.

If necessary, the second plate (3) can be designed with an additional pressure compensation chamber (not shown). Such a pressure equalization chamber compensates for a possible volume change in the temperature control medium when the temperature control apparatus is decoupled from the cooling circuit and the ambient temperature changes.

In such a design, the second plate (3) is still provided with a cover plate (14) such that the milled-in duct (4) is sealed.

Such a design is also possible for the first plate (2).

This exemplary embodiment shows two plates (6) which have a plurality of temperature sensors (5) which are mounted in such a way that they do not protrude from the plate. However, it is also possible to use only one plate (6). It is also possible to install only one temperature sensor in the plate (6). However, the temperature sensor(s) can also be integrated directly in the first plate (2) and/or in the second plate (3), again in such a way that the sensor or sensors do not protrude from the plate. If the sensor or sensors are installed in the first plate (2) and/or the second plate (3), no further plates (6) are required which accommodate the sensors. In order to lay the cables of the temperature sensors (5), milled-in portions are provided in this embodiment. With all the possibilities mentioned for positioning the temperature sensors (5), a local temperature measurement on the battery cell (1) is provided, and at the same time it is prevented that during assembly/pressurizing the battery cell (1) is damaged by the temperature sensors (5).

In the exemplary embodiment of the battery cell (1), the two spacer plates (7) ensure that the connectors (9) of the battery cell (1) rest flat on the plate (8) for electrical contacting. Thus, the connectors (9) are mechanically stressed as little as possible.

The plate (8) for electrical contacting is composed of 2 halves which are separated from one another.

The plate (8) for electrical contacting is used to connect the current from supplying contacts (15) to the battery cell (1).

In this embodiment, the supplying contacts (15) of the plate (8) for electrical contacting are designed on the front side.

By means of the congruent holes with which the plates are provided, the plates can be screwed together in the installation situation, for example, so that they all no longer shift relative to each other and a certain force acts on the battery cell.

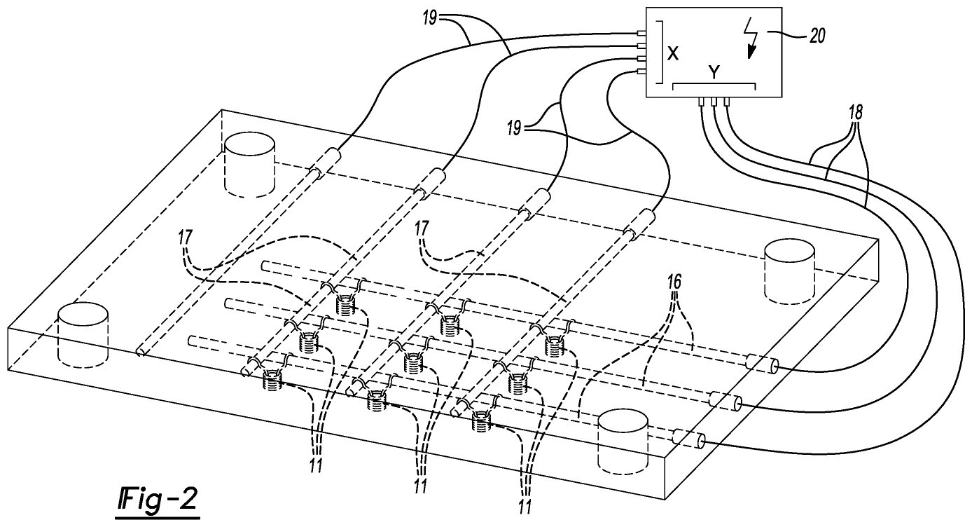

FIG. 2 shows an arrangement of temperature adjustment mechanisms (11) which are incorporated in that plate which comes into direct contact with the battery cell (1).

The advantage of such an arrangement is that different temperatures can be set on the surface of the battery cell (1) at different positions. It is advantageous if this plate has a good thermal conductivity so that it enables an almost unrestricted heat transfer between the plate and battery cell (1).

The depicted matrix form of the heating elements is controlled via lines (16, 17) of a current source. These lines are arranged in a type of matrix.

If a defined point on the battery cell (1) is to be heated, a corresponding line (16) of positive polarity and a corresponding line (17) of negative polarity are activated. The duration and current intensity used in this process determine the temperature which is set at the desired point.

If a plurality of points is to be heated on the battery cell (1), a plurality of lines (16) of positive polarity and a plurality of lines (17) of negative polarity are activated in a pulsed manner.

This then results in a temperature matrix on the battery cell (1). The control of the different lines (16, 17) as well as the pulsing and the necessary current intensity are assumed by control electronics (20).

The individual temperature adjustment mechanisms (11) are supplied via the lines (16) and (17). The control electronics (20) are connected to the heating matrix via cables (18) and (19).

If a temperature adjustment mechanism (11) is to be heated, the corresponding X position in the matrix is supplied by the control electronics (20) via the corresponding cable (19) and the corresponding y position is supplied with current via the corresponding cable (18).

The temperature adjustment mechanism (11) heats up, with the current and the switch-on duration determining which temperature is achieved by the temperature adjustment mechanism (11).

If a second temperature adjustment mechanism (11) is to be heated, a different x, y position in the matrix is supplied.

In order to generate a temperature matrix, that is to say a distribution of different temperatures at different locations, the switching on of the individual temperature adjustment mechanisms (11) is clocked. This is done in such a way that different temperature adjustment mechanisms (11) are supplied, for example, several times in one second, if necessary for different lengths of time and/or if necessary, with different currents. This results in different temperatures for different temperature adjustment mechanisms (11), if required.

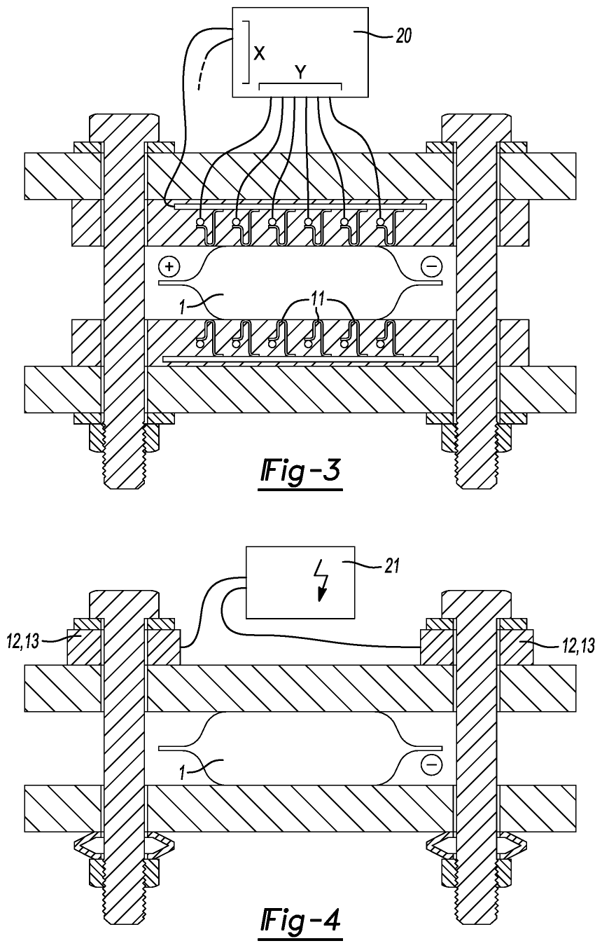

FIG. 3 depicts the installed battery cell (1) with two adjacent plates which have the temperature adjustment mechanisms (11) described in FIG. 2. These plates exert the pressure on the battery cell (1) which results from the bracing of the two outer plates by, for example, a bolt and a bolt nut. This pressure can be varied by tightening or releasing the bolt nut.

In addition, these outer plates can be provided with at least one duct through which a temperature control medium flows, so that heat can also be introduced or discharged with the aid of this temperature control medium.

As also described in FIG. 2, different temperature adjustment mechanisms (11) can also be controlled or operated in this embodiment by current flowing in the individual cable for the x position and for the y position.

This causes heating of the heating element (11) and thus a selective heating of the battery cell (1) at this point.

If a temperature matrix is to be achieved, here as well different temperature adjustment mechanisms are controlled in succession at defined positions. This takes place in a high cycle rate and with defined currents, which are determined by the control electronics (20).

FIG. 4 shows a battery cell (1) which is clamped between two plates. The two plates are connected to one another by screws, the screws having at least one piezocrystalline or piezoelectric spacer disk (12) or (13). By applying voltage to the piezocrystalline or piezoelectric spacer disks (12) or (13), a static or also a dynamic pressure change of the two plates on the battery cell (1) can be achieved.

Here the control of the piezocrystalline or piezoelectric spacer disk (12) or (13) can be effected with a pulse-width-modulated signal.

However, the piezocrystalline or piezoelectric spacer disks (12) or (13) can also be used to determine the pressure that is currently being applied to the battery cell (1). This is done by measuring the voltage generated by the piezocrystalline or piezoelectric spacers disks (12) or (13) under this pressure. The pressure can be deduced from this.

With such an arrangement, the possibly changed pressure due to the age-related mechanical pretension can be compensated.

Here the control of the piezocrystalline or piezoelectric spacer disks (12) or (13) can be carried out with control electronics (21). These control electronics (21) make it possible to control the piezocrystalline or piezoelectric spacer disks (12) or (13) with both a static and a dynamic signal. Thus, various “pressure” effects can be produced. Furthermore, the control electronics (21) can be used for compensation in order to compensate for existing temperature and time behavior.

Furthermore, a disk spring can be used in order to be able to adjust the application of pressure to the battery cell (1) more finely when tightening the bolt nut.

An embodiment as shown in simplified form in FIG. 4 can clearly be combined with all possible embodiments of the claims and the other figures. Likewise, any other machine element that has a similar effect or function can be used instead of the piezocrystalline or piezoelectric spacer disks (12) or (13).

During operation, the pressure can be measured and changed via the control of the piezocrystalline or piezoelectric spacer disks (12) or (13).

The piezocrystalline or piezoelectric spacer disks (12) or (13) are controlled with a pulsed signal. This prevents the piezocrystalline or piezoelectric spacer disks (12) or (13) from running away in terms of their pressure, as is the case with a constant control signal.

The pulsed control signal results in a medium pressure between the two plates which is applied to the battery cell (1).

An aging of the disk springs can also be compensated by the combination of measuring and controlling the piezocrystalline or piezoelectric spacer disk (12) or (13).

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A temperature control device for receiving a battery, the temperature control device comprising:
a first plate;
a second plate, wherein:
a battery cell is positionable between the first and second plates; and
at least one of the first and second plates is provided with at least one channel through which coolant is flowable; and
a coupling configured to releasably connect the at least one channel to a cooling system.

2. The temperature control device of claim 1 further comprising at least one temperature sensor mounted to a side of at least one of the first and second plates configured to face the battery cell, wherein the at least one temperature sensor does not protrude from the at least one of the first and second plates.

3. The temperature control device of claim 1 further comprising a third plate having a temperature sensor that does not protrude from the third plate.

4. The temperature control device of claim 1 further comprising spacer plates configured to surround the battery cell, wherein the thickness of all the spacer plates is substantially equal to the thickness of the battery cell.

5. The temperature control device of claim 4 further comprising a third plate for electrically contacting the battery cell.

6. The temperature control device of claim 5 wherein the spacer plates are configured to enclose the battery cell in such a way that at least two connectors of the battery cell can rest flush on the third plate.

7. The temperature control device of claim 5 wherein the coupling is automatically actuated and thereby enables automatable connection of the temperature control device to the cooling system.

8. The temperature control device of claim 1 wherein at least one of the first and second plates has at least one temperature adjustment mechanism configured to independently adjust the temperature of the battery cell at multiple locations.

9. The temperature control device of claim 1 further comprising a force sensor configured to measure a force that acts on the battery cell.

10. The temperature control device of claim 1 further comprising an actuator configured to maintain a constant clamping force on the battery cell as the battery cell expands.

11. The temperature control device of claim 1 further comprising at least one of a force sensor and an actuator, wherein:
the force sensor is configured to measure a force that acts on the battery cell;
the actuator is configured to maintain a constant clamping force on the battery cell as the battery cell expands; and
at least one of the force sensor and the actuator includes at least one of a piezocrystalline device, a piezoelectric device, and a magnetostrictive device.

12. A system including at least two temperature control devices connected to a coolant source, each of the at least two temperature control devices comprising:
a first plate; and
a second plate, wherein:
a battery cell is positionable between the first and second plates;
at least one of the first and second plates is provided with at least one channel through which coolant is flowable; and
the at least two temperature control devices are individually separable from the system.

13. The system of claim 12 wherein the coolant source includes at least one pressure accumulator.

14. The system of claim 12 wherein the coolant source includes a pressure relief valve configured to allow coolant to escape.

15. The system of claim 12 further comprising a coupling releasably connecting the at least one channel to the coolant source.

16. The system of claim 15 wherein the coupling is automatically actuated.

17. The system of claim 12 further comprising at least one temperature sensor mounted to a side of at least one of the first and second plates configured to face the battery cell, wherein the at least one temperature sensor does not protrude from the at least one of the first and second plates.

18. The system of claim 12 further comprising a third plate having a temperature sensor that does not protrude from the third plate.

19. The system of claim 12 further comprising spacer plates configured to surround the battery cell, wherein the thickness of all the spacer plates is substantially equal to the thickness of the battery cell.

20. The system of claim 12 further comprising a third plate for electrically contacting the battery cell.
